(19) United States
(12) Patent Application Publication
(10) Pub. No.: US 2005/0271516 A1
(43) Pub. Date: Dec. 8, 2005

(54) Fan louver having its outlet grill and inlet grill each consisting of detachable sectors

(76) Inventors: S. C. Chang, Gukang Village (TW); Hung Ching Liu, Gukang Village (TW)

Correspondence Address: PRO-TECHTOR INTERNATIONAL, 20775 Norada Court, Saratoga, CA, 95070-3018, US

(21) Appl. No.: 10/862,957

(22) Filed: Jun. 7, 2004

(51) Int. Cl. G11C 11/34

(52) U.S. Cl. 416/247 R

(57) ABSTRACT

A fan louver comprises detachable outlet and inlet grills. The outlet grill comprises detachable first sectors each comprising holed first projections along one radius and first latched members along the other radius, the first latched members of one first sector being secured to the first projections of an adjacent first sector and the first projections thereof being secured to the first latched members of another adjacent first sector. The inlet grill comprises detachable second sectors each comprising holed second projections along one radius and second latched members along the other radius, the second latched members of one second sector being secured to the second projections of an adjacent second sector and the second projections thereof being secured to the second latched members of another adjacent second sector.

### FIELD OF THE INVENTION

The present invention relates to electric fans and more particularly to such an electric fan having its louver having its outlet grill and inlet grill each including a plurality of detachable sectors.

### BACKGROUND OF THE INVENTION

Conventionally, outlet grill and inlet grill of louver of an electric fan are separate, connectable members. However, either outlet grill or inlet grill is an integral member. From the point of view of manufacture, it has the benefit of decreasing the number of fan components. However, it may hinder delivery because a large space is occupied by the outlet grill and the inlet grill. The required space is even larger if the electric fan has a large size. Thus, it is desirable to provide a fan louver having its outlet grill and inlet grill each including a plurality of detachable sectors in order to overcome the above drawback of prior art.

### SUMMARY OF THE INVENTION

It is an object of the present invention to provide an electric fan having a louver comprising an outlet grill including a plurality of spaced, holed protrusions along periphery; and an inlet grill including a plurality of latched elements along periphery, the latched elements being inserted into the holes of the protrusions for snappingly securing thereto; wherein the outlet grill comprises a plurality of detachable first sectors each comprises a plurality of spaced, holed first projections along one radius and a plurality of spaced first latched members along the other radius, the first latched members of one first sector being secured to the first projections of an adjacent first sector and the first projections thereof being secured to the first latched members of another adjacent first sector; and the inlet grill comprises a plurality of detachable second sectors each comprises a plurality of spaced, holed second projections along one radius and a plurality of spaced second latched members along the other radius, the second latched members of one second sector being secured to the second projections of an adjacent second sector and the second projections thereof being secured to the second latched members of another adjacent second sector. By utilizing the present invention, the storage space of the louver can be greatly reduced for ease of delivery.

The above and other objects, features and advantages of the present invention will become apparent from the following detailed description taken with the accompanying drawings.

### BRIEF DESCRIPTION OF THE DRAWINGS

FIG. 1 is a perspective view of a preferred embodiment of electric fan according to the invention;

FIGS. 2 and 3 are sectional views showing an outlet grill to be assembled with an inlet grill and the outlet grill assembled therewith respectively; and

FIG. 4 is an exploded perspective view of the outlet grill;

FIGS. 5 and 6 are sectional views showing one radius of a sector of the outlet grill to be assembled with the other radius of an adjacent sector thereof and one radius assembled therewith respectively; and

FIG. 7 is an exploded perspective view of the inlet grill; and

FIGS. 8 and 9 are sectional views showing one radius of a sector of the inlet grill to be assembled with the other radius of an adjacent sector thereof and one radius assembled therewith respectively.

### DETAILED DESCRIPTION OF THE PREFERRED EMBODIMENTS

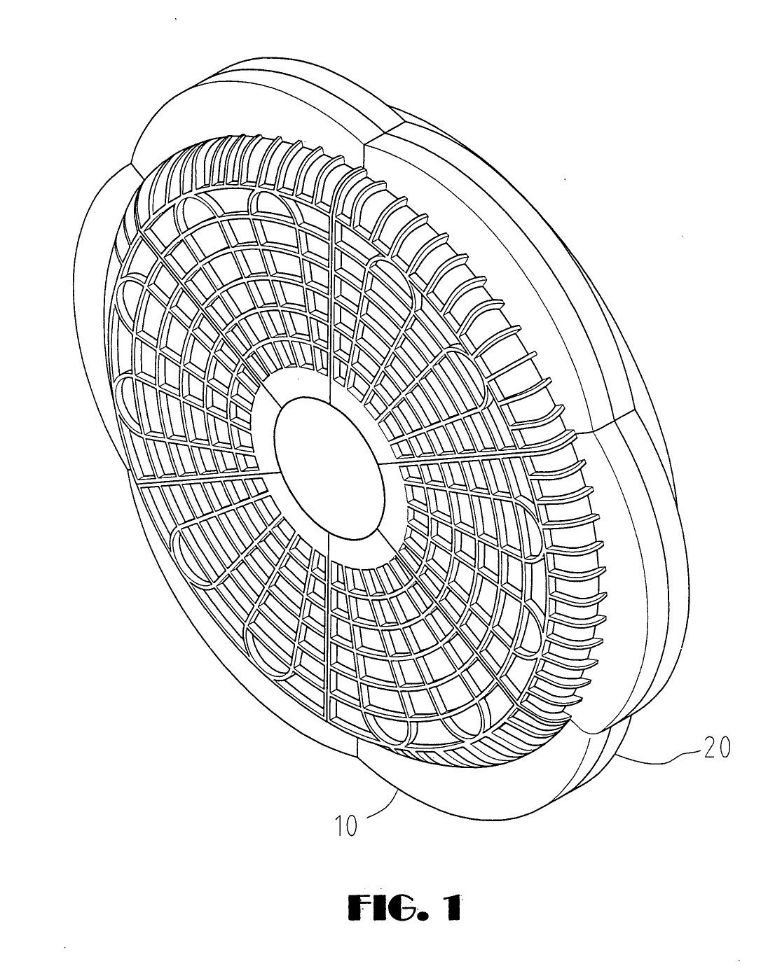

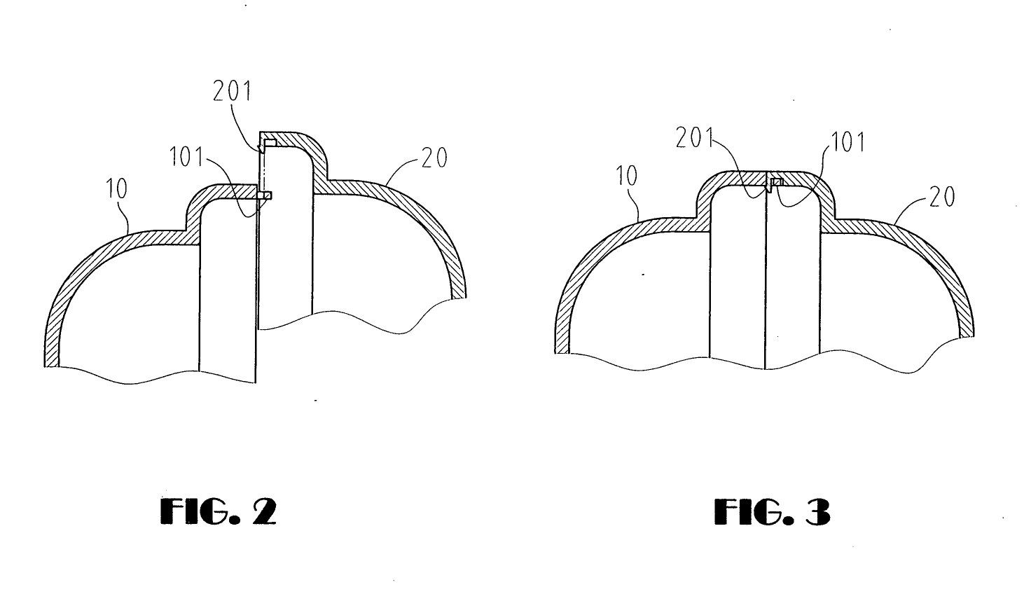

Referring to FIGS. 1 to 3, there is shown an electric fan having a louver constructed in accordance with the invention. The louver comprises an outlet grill 10 including a plurality of spaced, holed projections 101 along periphery and an inlet grill 20 including a plurality of latched members 201 along periphery, the latched members 201 being inserted into the holes of the projections 101 for snappingly securing thereto.

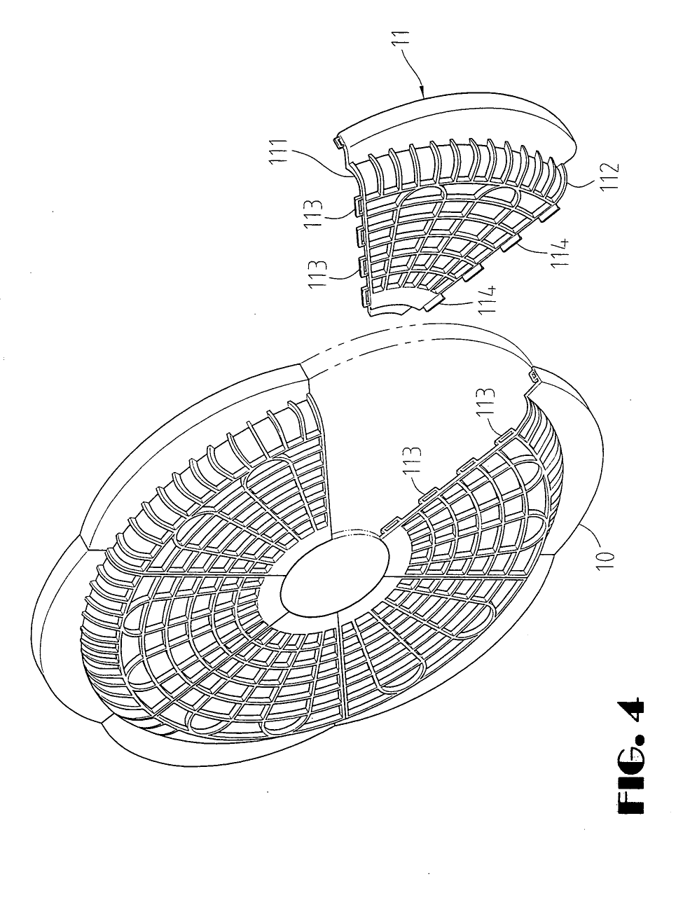

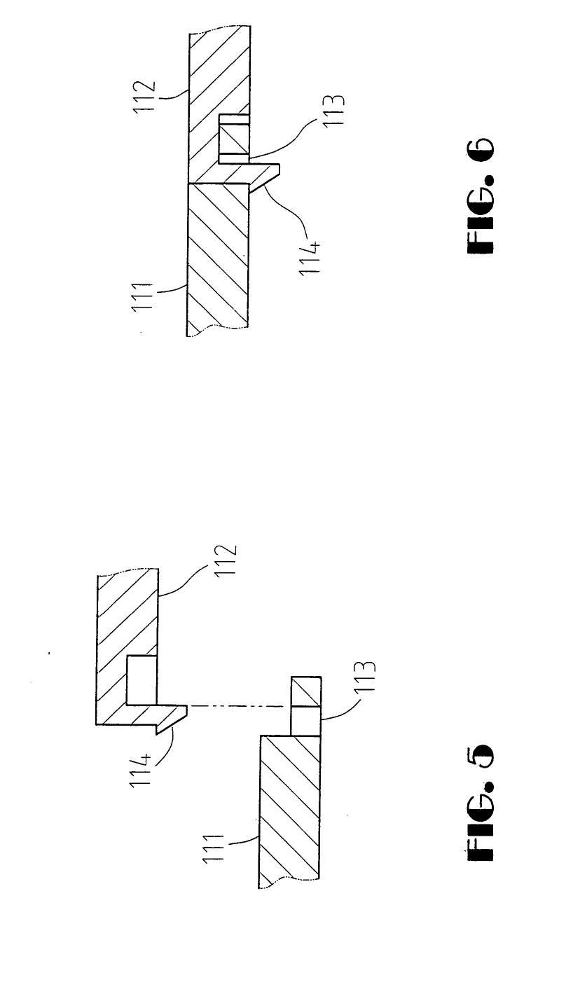

Referring to FIGS. 4 to 6, the outlet grill 10 comprises a plurality of detachable sectors 11 each including a plurality of spaced, holed projections 113 along one radius 111 and a plurality of spaced latched members 114 along the other radius 112. The latched members 114 of one sector 11 are secured to the projections 113 of an adjacent sector 11 and/or the projections 113 of one sector 11 are secured to the latched members 114 of another adjacent sector 11 when one sector 11 is snapped into one of at least one unoccupied sector area of the outlet grill 10.

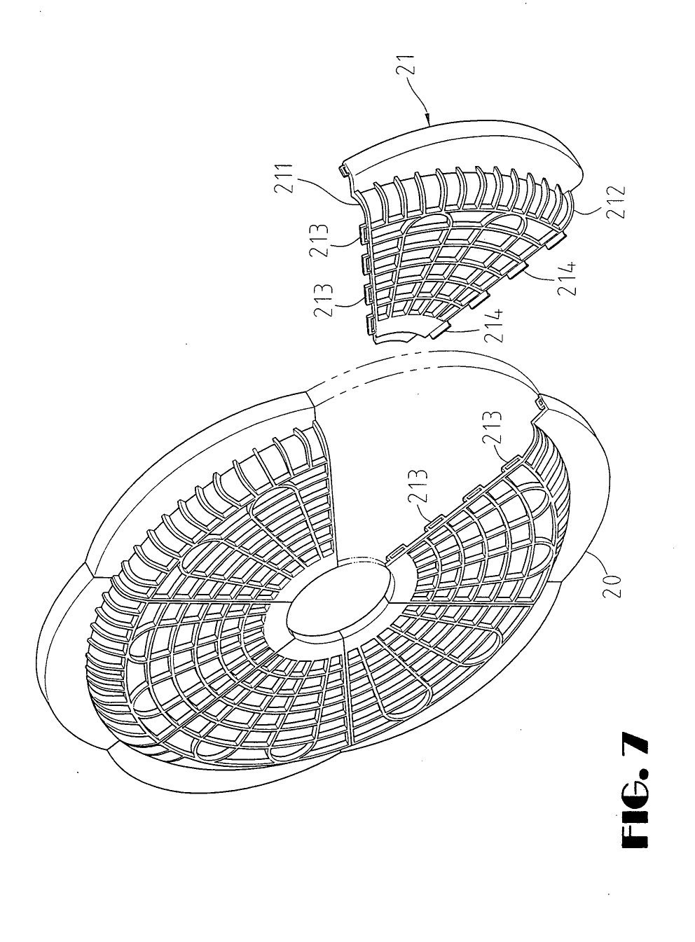

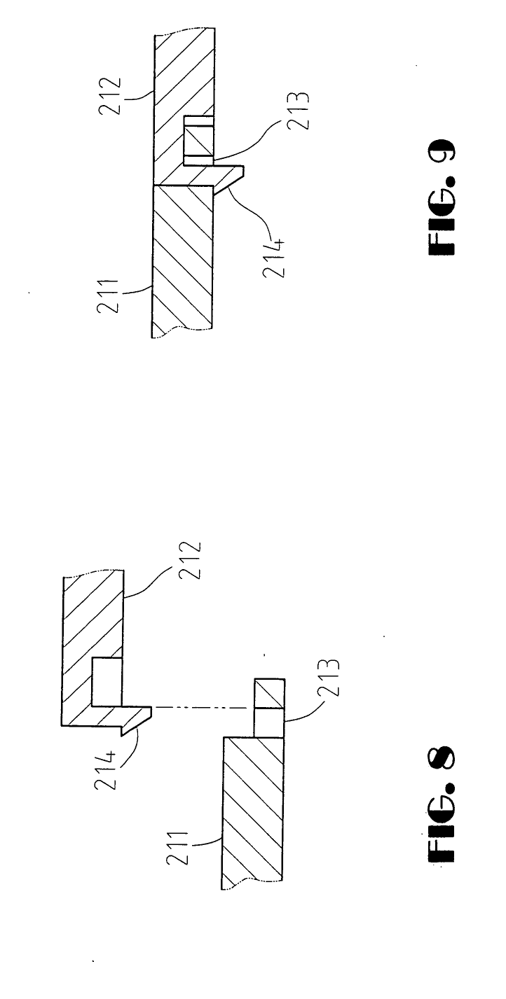

Referring to FIGS. 7 to 9, the inlet grill 20 comprises a plurality of detachable sectors 21 each including a plurality of spaced, holed projections 213 along one radius 211 and a plurality of spaced latched members 214 along the other radius 212. The latched members 214 of one sector 21 are secured to the projections 213 of an adjacent sector 21 and/or the projections 213 of one sector 21 are secured to the latched members 214 of another adjacent sector 21 when one sector 21 is snapped into one of at least one unoccupied sector area of the inlet grill 20.

While the invention herein disclosed has been described by means of specific embodiments, numerous modifications and variations could be made thereto by those skilled in the art without departing from the scope and spirit of the invention set forth in the claims.

1. An electric fan having a louver comprising:
an outlet grill including a plurality of spaced, holed protrusions along periphery; and
an inlet grill including a plurality of latched elements along periphery, the latched elements being inserted into the holes of the protrusions for snappingly securing thereto;
wherein the outlet grill comprises a plurality of detachable first sectors each comprises a plurality of spaced, holed first projections along one radius and a plurality of spaced first latched members along the other radius, the first latched members of one first sector being secured to the first projections of an adjacent first sector and the first projections thereof being secured to the first latched members of another adjacent first sector; and
the inlet grill comprises a plurality of detachable second sectors each comprises a plurality of spaced, holed second projections along one radius and a plurality of spaced second latched members along the other radius, the second latched members of one second sector being secured to the second projections of an adjacent second sector and the second projections thereof being secured to the second latched members of another adjacent second sector.
